(19) United States
(12) Patent Application Publication
(10) Pub. No.: US 2023/0377896 A1
(43) Pub. Date: Nov. 23, 2023

(54) BACK SURFACE PLASMA DICED WAFERS AND METHODS THEREOF

(71) Applicant: UTAC Headquarters Pte. Ltd.

(72) Inventors: Jackson Fernandez Rosario, Singapore (SG); Enrique E. Sarile Jr, Singapore (SG); Dzafir Bin Mohd Shariff, Singapore (SG); Ronnie M. De Villa, Singapore (SG); Chan Loong Neo, Singapore (SG); Phongsak Sawasdee, Bangkok (TH)

(21) Appl. No.: 18/319,452

(22) Filed: May 17, 2023

Related U.S. Application Data
(63) Continuation-in-part of application No. 18/175,124, filed on Feb. 27, 2023.
(60) Provisional application No. 63/343,061, filed on May 17, 2022.
(60) Provisional application No. 63/367,324, filed on Jun. 29, 2022.
(60) Provisional application No. 63/367,325, filed on Jun. 29, 2022.

(51) Int. Cl. H01L 21/3065; H01L 21/683; H01L 23/31; H01L 23/495; H01L 23/00

(52) U.S. Cl. CPC H01L 21/3065; H01L 21/6836; H01L 23/3107; H01L 23/4952; H01L 24/48; H01L 2221/68327; H01L 2221/6834; H01L 2224/48247; H01L 2924/181

(57) ABSTRACT

Disclosed is a plasma diced die from the backside of the wafer using a back surface mask layer. The back surface mask layer remains on the backside of the die, serving as backside protection for the die. The plasma dicing may dice the wafer completely or partially. In the case of partial dicing, the partially diced wafer is expanded to singulate the wafer into individual dies by lateral force.

### CROSS-REFERENCE TO RELATED APPLICATION

This application is a continuation-in-part of the US patent application filed on Feb. 27, 2023, with application Ser. No. 18/175,124, titled “PLASMA DICED WAFERS AND METHODS THEREOF”. This application also claims the benefit of U.S. Provisional Application No. 63/343,061, filed on May 17, 2022, U.S. Provisional Application Ser. No. 63/367,324, filed on Jun. 29, 2022, and U.S. Provisional Application Ser. No. 63/367,325, filed on Jun. 29, 2022. All disclosures are herein incorporated by reference for all purposes.

### FIELD OF THE INVENTION

The present disclosure generally relates to plasma dicing of semiconductor wafers. More specifically, the present disclosure is directed to reliable dies from plasma dicing from the back surface of the wafer.

### BACKGROUND

In semiconductor processing, a wafer is processed to form a plurality of devices thereon. After the devices are formed, the wafer is diced to separate the devices into individual dies. Conventional techniques for dicing employ the use of a dicing saw. The saw cuts the wafer along the x-direction and the y-direction saw lines, one at a time, to separate the wafer into individual dies. Sawing, however, takes time, which slows down the processing throughput. In addition, mechanical sawing causes vibration when cutting the wafer. The vibration may cause cracks in the dies, such as the back-end dielectric, which may impact yields negatively.

To combat the issues of sawing, plasma dicing has been investigated. Plasma dicing entails mounting a wafer onto a wafer ring and inserting the wafer ring with the wafer into a plasma chamber for etching. Unlike mechanical sawing, the plasma etch process singulates the wafer into individual dies in a single plasma etch step without any vibration issues. This significantly improves throughput as well as avoids reliability issues due to cracking.

The present disclosure is directed to reliable plasma dicing from the back surface of the wafers for singulating it into individual dies.

### SUMMARY

Reliable plasma dicing of wafers is disclosed. In one embodiment, the present disclosure is related to a device. The device includes a die with first and second major die surfaces. The device also includes a die with die sidewall and a portion of the die sidewalls extending from the second major die surface towards the first major die surface includes scalloped-shaped sidewalls. The device further includes a die with a mask layer disposed on the second major die surface.

In another embodiment, a semiconductor package is disclosed. The semiconductor package includes a lower leadframe. The lower leadframe includes lower leadframe top surface, lower leadframe bottom surface, lower leadframe pads on the lower leadframe top surface, a die attach region on the lower leadframe top surface, and lower leadframe package contacts on the lower leadframe bottom surface. The lower leadframe package contacts are coupled to the lower leadframe pads. The semiconductor package also includes an upper leadframe. The upper leadframe includes upper leadframe top surface, upper leadframe bottom surface, upper leadframe pads on the upper leadframe top surface, and upper leadframe package contacts on the upper leadframe top surface. The upper leadframe package contacts are coupled to the upper leadframe pads. The semiconductor package further includes a die with active and inactive die surfaces. The inactive die surface is attached to the die attach region of the lower leadframe package and the active die surface includes die pads. The semiconductor package also includes wire bonds connecting the die pads to the upper and lower leadframe pads, and an encapsulant encapsulating the upper and lower leadframes, the die and the wirebonds. The upper and lower package contacts are exposed by the encapsulant.

In yet another embodiment, a method of forming devices is disclosed. The method includes providing a wafer. The wafer includes a first major surface and a second major surface. The method also includes forming a mask layer on the second wafer surface and patterning the mask layer to form a patterned mask layer with openings corresponding to dicing channels in x and y directions. The method further includes plasma dicing the wafer using the patterned mask layer and singulating the wafer into individual die.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily drawn to scale, with emphasis instead generally being placed upon illustrating the principles of the invention. In the following description, various embodiments of the present invention are described with reference to the following drawings, in which:

FIG. 1a shows a simplified top view of an embodiment of a processed wafer;

FIG. 1b shows a simplified cross-sectional view of a portion of a processed wafer which includes a saw street between two adjacent dies;

FIGS. 2a-2d show simplified cross-sectional views of various embodiments of plasma diced dies;

FIG. 3a shows a simplified cross-sectional view of a setup for a processed wafer in preparation for plasma dicing;

FIGS. 3b-3e show various embodiments of process flows for dicing a processed wafer from the back surface;

FIGS. 4a-4f show simplified cross-sectional views depicting a process for plasma dicing a wafer;

FIGS. 5a-5d show simplified cross-sectional views depicting another process for plasma dicing a wafer;

FIGS. 6a-6e show simplified cross-sectional views depicting yet another process for plasma dicing a wafer;

FIGS. 7a-7d show simplified cross-sectional views depicting another process for plasma dicing a wafer; and

FIGS. 8a-8b show simplified cross-sectional views of embodiments of packages.

### DETAILED DESCRIPTION

Embodiments relate to plasma dicing of a wafer from its back surface to singluate it into individual dies. The plasma dicing, according to various embodiments, results in reliable plasma-diced dies. The present plasma wafer dicing avoids notching on the backside of the wafer or dies, improving process reliability and yields. In addition, the plasma diced dies include a backside mask layer attached on the inactive surface of the die substrate, improving die strength, stability, and shear, resulting in improved reliability of the dies.

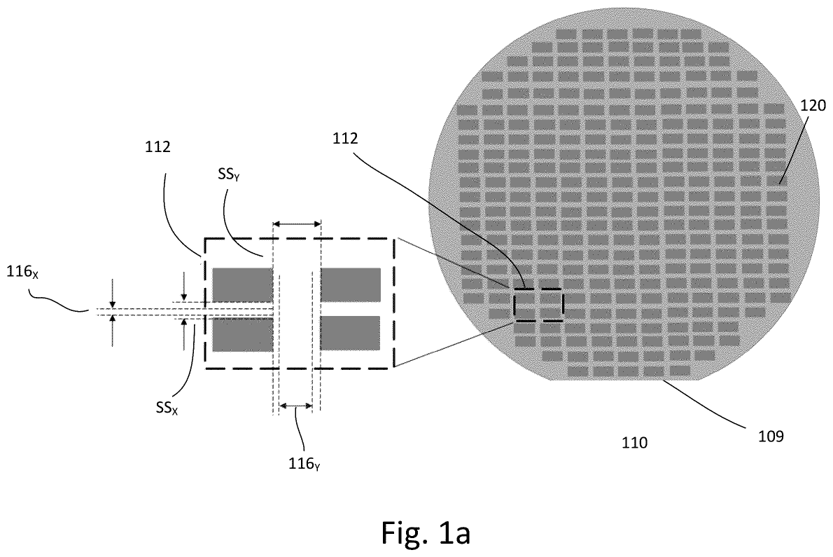

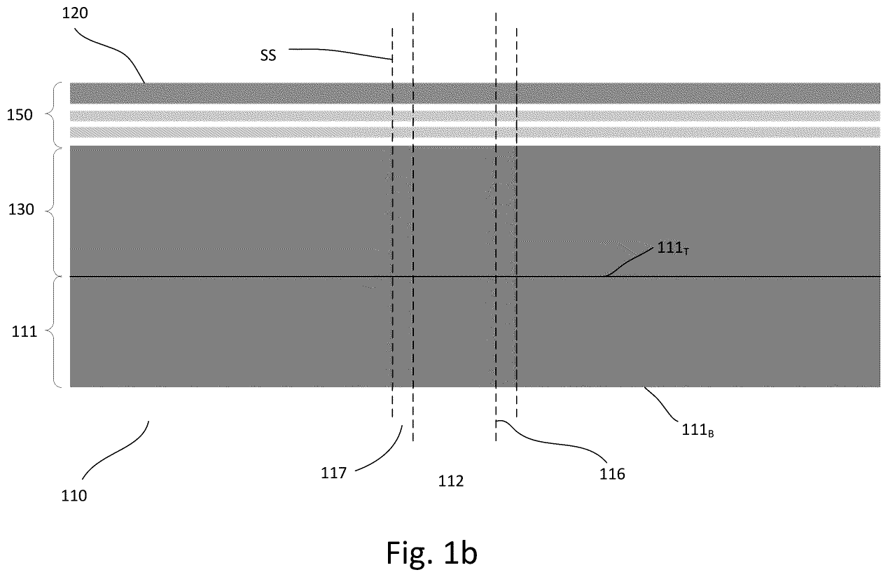

FIG. 1a shows a top view of an embodiment of a wafer 110. The wafer, as shown, is a semiconductor wafer with first and second major surfaces. For example, the semiconductor wafer may be a silicon wafer. Other types of semiconductor wafers may also be useful. On a first or active (frontside) surface, the wafer is processed to form a plurality of dies 120. The dies, for example, are arranged in rows (x-direction) and columns (y-direction). Separating the rows and columns of dies are first and second saw streets or dicing lines. For example, x-direction dicing lines SSₓ and y-direction dicing lines SS_{y} separate the rows and columns of dies on the wafer. The wafer may include a notch 109 for orientation purposes. For example, the notch may be a flat edge of the wafer. Other features or techniques for orienting the wafer may also be useful.

A detailed portion 112 of the wafer which includes adjacent dies in the x-direction and y-direction is shown. As shown, a saw street includes a kerf region within the saw street. For example, an x-direction saw street SS_{X} includes an x-direction kerf region 116ₓ disposed within the saw street. Likewise, a y-direction saw street SS_{y} includes a y-direction kerf region 116y within the saw street. In one embodiment, the kerf region may be about 70 to 80% of the saw street width. Other kerf region widths with respect to the width of the saw street may also be useful.

As shown, the saw streets are defined by the edges of the dies in adjacent rows and columns. A kerf region, as shown, is disposed within the saw streets. Typically, test circuitry is disposed within the kerf region for testing the dies on the wafer. During plasma dicing, the kerf region is removed. For example, the gap regions between the kerf regions and saw streets remain after plasma dicing. Other configurations of the saw streets and kerf regions may also be useful.

FIG. 1b shows a simplified cross-sectional view of a portion 112 of a processed wafer 110 which includes a saw street SS between two adjacent dies 120 of a row or a column. As shown, a wafer 111 serves as a substrate for processed dies 120. In one embodiment, the wafer is processed to form dies in parallel separated by orthogonal saw streets SS in the x-direction and y-direction. As shown, between a saw street SS is the kerf region 116. Gap regions 117 exist between a saw street and a kerf region.

In general, the fabrication of devices may involve the formation of features on a wafer that makes up circuit components, such as transistors, resistors, capacitors as well as other circuit components. The components are interconnected, enabling the device to perform the desired functions. To form the features and interconnections, layers are repeatedly deposited on the wafer and patterned as desired using lithographic techniques. For example, a wafer is patterned by exposing a photoresist layer with an exposure source using a reticle containing the desired pattern. After exposure, the photoresist layer is developed, transferring the pattern of the reticle to the photoresist layer. This forms a photoresist etch mask. An etch is performed using the etch mask to replicate the pattern on the wafer below, which may include one or more layers, depending on the stage of the process. In the formation of the devices, numerous reticles may be used for different patterning processes.

In one embodiment, features corresponding to the circuit components are formed in, on or above a major surface of the wafer. The surface of the wafer may be referred to as an active or top surface 111_{T} of the wafer. For example, doped regions serving as wells, S/D contacts and well contacts may be formed by ion implantation processes in the substrate while other features, such as gates, capacitors, resistors, isolation regions and other components, may be formed on and above the surface of the substrate. The opposing surface of the active surface may be referred to as an inactive or bottom surface 111B.

A back-end-of-line dielectric (BEOL) 130 may be formed on the substrate over the circuit components. The BEOL dielectric layer includes a pre-metal interlayer dielectric (ILD) layer disposed over the circuit components and a plurality of intermetal dielectric (IMD) layers disposed over the pre-metal ILD layer. The number of IMD layers may be depending on the CMOS process or technology.

The pre-metal ILD layer includes pre-metal contacts which are connected to contact regions of the components. For example, the pre-metal contacts are connected to S/D regions, transistor gates and well contacts. The pre-metal contacts, for example, may be tungsten (W) contacts. Other types of contacts may also be useful. The pre-metal ILD layer may be formed from multiple dielectric layers. Various dielectric materials, such as silicon oxide (SiO₂), may be used to form the pre-metal ILD layer.

As for an IMD layer, it includes a metal dielectric layer below a via dielectric level. The dielectric layers of the IMD layer may be SiO₂. Other types of dielectric materials or combinations of dielectric materials or layers may also be useful to form the IMD layer. The metal level includes metal lines and the via level includes via contacts. The uppermost metal level may serve as a pad level in which bond pads for external connections to the dies are disposed. The metal lines and via contacts may be formed using damascene techniques, such as a single or a dual damascene process. In the case of a single damascene process, the contacts and metal lines are formed in separate processes. In the case of a dual damascene process, the metal lines and contacts are formed in the same process. Other configurations of the IMD layers may also be useful.

Above the BEOL dielectric is a passivation stack 150. The passivation stack includes multiple dielectric passivation layers. For example, the passivation layer may include silicon oxide, silicon nitride and/or silicon oxynitride layers. The uppermost layer may be silicon nitride. For example, the uppermost passivation layer can be etched selectively from the BEOL dielectric. Other configurations of the passivation layer or stack may also be useful. The passivation layer or stack protects the die. Passivation stack may also be used to refer to a passivation layer. Bond openings may be formed in the passivation stack to expose the bond pads. Bond openings facilitate interconnecting the die and the package substrate during the package assembly process. In one embodiment, the passivation stack is patterned to define openings for plasma dicing of the wafer to singulate it into individual dies. The openings may be formed by laser patterning or etching. For example, a laser grooving process is employed to form the openings in the passivation stack. In one embodiment, the openings correspond to the kerf region within the saw streets. For example, the openings correspond to the dicing channels of the wafer. The plasma dicing process removes the kerf regions, leaving the gap regions remaining.

In other embodiments, the wafer may be a blank or an unprocessed wafer. For example, the wafer has not been processed to form dies thereon. In such cases, plasma dicing produces blank dies. The blank dies may be employed as stiffeners in multi-level packages.

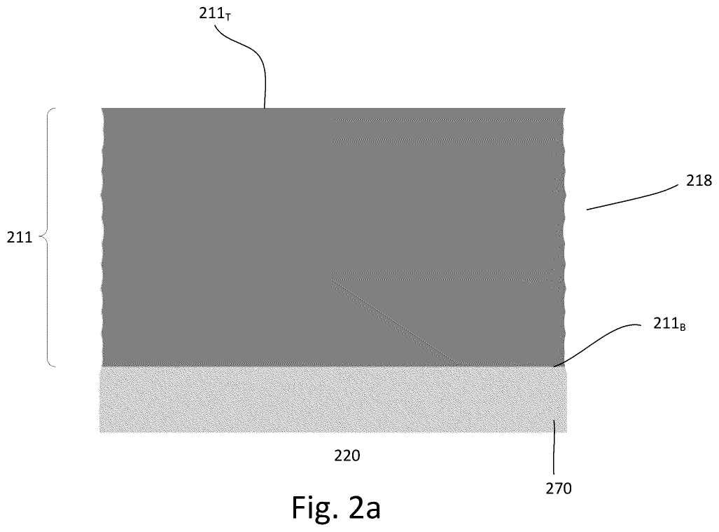

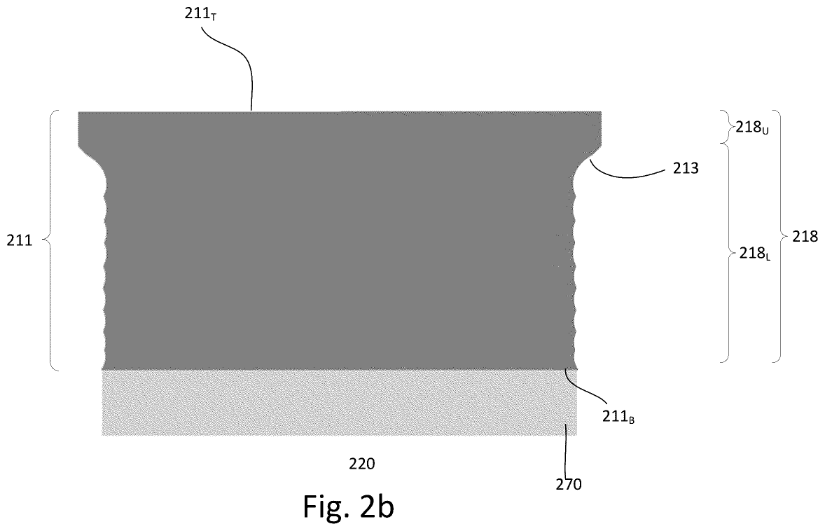

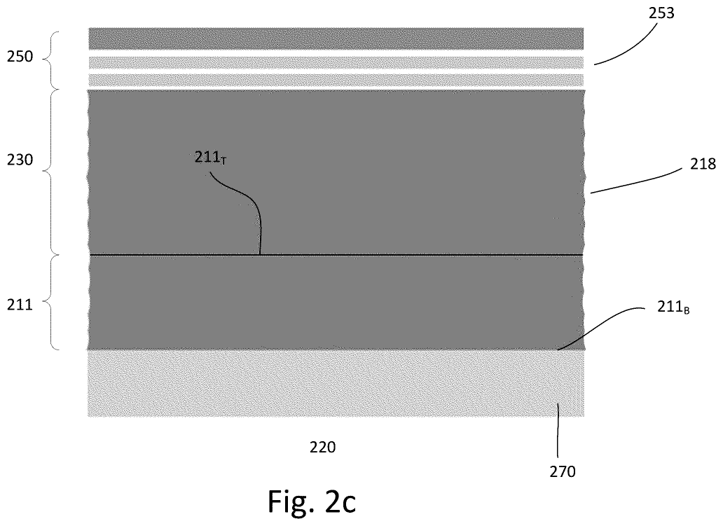

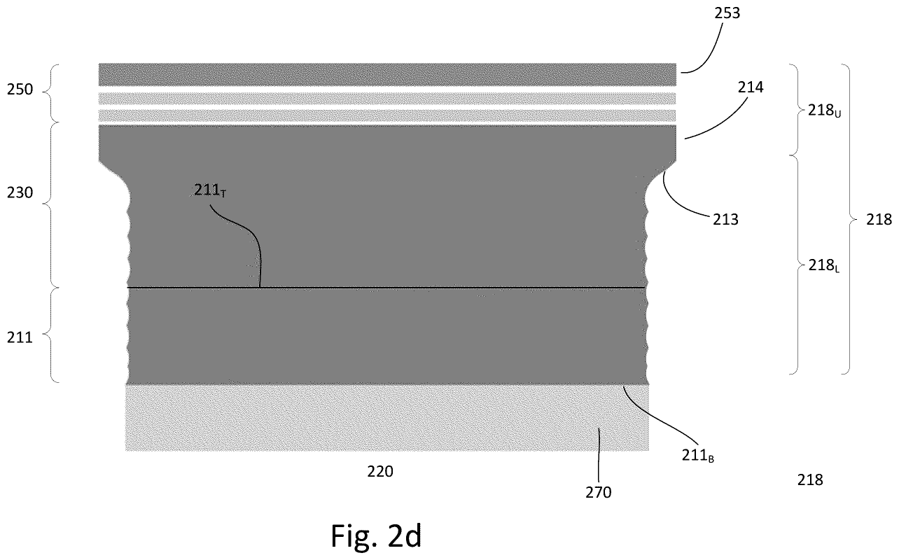

FIGS. 2a-2d show simplified cross-sectional views of various embodiments of a plasma diced die 220. The cross-section view may be along the x-direction or the y-direction. The die is preferably rectangular-shaped. Other shaped die may also be useful.

Referring to FIG. 2a, the die 220 is a blank die. For example, the die includes an unprocessed substrate 211. The substrate, for example, is part of a blank or unprocessed wafer before singulation. The blank substrate includes a top surface 211_{T} and a bottom surface 211_{B}. In one embodiment, the top surface is a bare or unprocessed substrate surface. As for the bottom surface, a bottom surface (BS) mask 270 layer is disposed thereon. In one embodiment, the BS mask layer is an infrared (IR) mask layer. Other types of BS mask layers may also be useful. For example, the BS mask layer may be a die attach film (DAF). The BS mask layer may be a laminated mask layer. For example, the mask layer is laminated to the bottom surface of the unprocessed wafer.

In one embodiment, the BS mask layer is a patterned mask layer. For example, after attachment to the bottom surface of the unprocessed wafer, it is patterned to expose saw streets of the unprocessed wafer. For example, dicing channels for plasma dicing are exposed. Patterning the mask layer may be achieved by laser ablation or by mechanical dicing, such as sawing. For example, the mask layer sidewalls may be laser ablated or sawed surfaces. The sidewalls are vertical sidewalls. By vertical, they are perpendicular to the top or bottom horizontal surface of the unprocessed wafer. The patterned mask layer serves as an etch mask for plasma dicing of the blank wafer. For example, plasma dicing is performed from the back or bottom surface of the wafer to singulate it into individual blank dies.

The substrate sidewalls of the blank die, as shown, include scalloped sidewalls 218. The scalloped sidewalls, in one embodiment, result from a plasma dicing process using deposition and etch cycles. For example, each deposition and etch cycle forms a scalloped sub-portion. The scalloped sidewalls, as such, are plasma-etched sidewall surfaces.

FIG. 2b shows another embodiment of a blank die 220. The blank die is similar to that described in FIG. 2a. Common elements may not be described or described in detail.

The blank die includes an unprocessed substrate 211 with top and bottom surfaces 211_{T} and 211_{B}. Attached to the bottom surface of the substrate is a BS mask layer with vertical mask sidewalls. In one embodiment, the BS mask layer is a patterned mask layer which serves as a plasma etch mask for plasma dicing the unprocessed wafer to form blank dies. The mask layer includes vertical sidewalls which may be laser ablated or sawed surfaces.

The substrate sidewalls of the blank die, as shown, include upper and lower substrate sidewall portions 218_{U} and 218_{L}. As shown, the upper substrate sidewall portion extends outwards away from the lower substrate sidewall portion, creating a foot 213. The upper sidewall portion, for example, is about 10-20% of the total thickness of the substrate while the lower portion is about 80-90% of the total thickness of the substrate. In one embodiment, the upper substrate portion includes a vertical or substantially vertical upper substrate sidewall surface and the lower substrate sidewall portion includes a scalloped sidewall from plasma dicing. The profile of the foot is formed by the partial plasma dicing of the wafer which is subsequently singulated by lateral force from laterally stretching the partially diced blank wafer away from the center of the wafer. As such, the lower substrate sidewall portion includes a plasma diced surface and the upper substrate sidewall portion includes a force separated surface.

FIG. 2c shows an embodiment of a processed die 220. The processed die includes similar characteristics and elements as the blank die described in FIG. 2a. Common elements may not be described or described in detail.

The processed die includes a substrate 211 processed with circuit components on the active or top surface 211_{T}. Above the active substrate surface is a BEOL dielectric 230 with interconnections interconnecting the circuit components. For example, the BEOL dielectric includes an ILD layer with multiple IMD layers thereover. An uppermost metal level dielectric of the IMD layer may serve as a pad level with bond pads.

A passivation stack 250 is disposed over the top of the BEOL dielectric. For example, the passivation stack is disposed over the pad level with bond pads. In one embodiment, the passivation stack includes multiple dielectric passivation layers. For example, the passivation layer may include silicon oxide, silicon nitride and/or silicon oxynitride layers. Other configurations of passivation stacks may also be useful. The passivation stack may include pad openings (not shown) to expose the bond pads for external connections to the internal circuit components of the die. For example, power and input/output (I/O) connections are provided via the bond pads.

In one embodiment, the passivation stack includes flat sidewalls 253. The flat sidewalls form planar surfaces. For example, the passivation stack includes 2 pairs of opposing flat sidewalls. In one embodiment, the flat sidewalls are in the vertical direction. For example, the vertical sidewall walls are orthogonal to the major surfaces of the wafer or substrate of the die, such as the top or bottom substrate surface. The vertical sidewalls are formed by the mask opening process to define the plasma dicing mask. In one embodiment, the vertical sidewalls are formed by laser patterning. For example, the passivation sidewall surfaces may be laser etched or ablated surfaces. Other techniques for patterning the passivation stack may also be useful. For example, a reactive ion etch (RIE) using a patterned mask, such as photoresist, may be employed.

As for the bottom surface 211_{B} of the wafer, a bottom surface (BS) mask layer 270 is disposed thereon. In one embodiment, the BS mask layer is an infrared (IR) mask layer. The BS mask layer may be a laminated mask layer. For example, the mask layer is laminated to the bottom surface of the processed wafer.

In one embodiment, the BS mask layer is a patterned mask layer. For example, after attachment to the bottom surface of the processed wafer, it is patterned to the dicing channels or kerf regions. Patterning the mask layer may be achieved by laser ablation or by mechanical dicing, such as sawing. For example, the mask layer sidewalls may be laser ablated or sawed surfaces. The sidewalls are vertical sidewalls. The patterned mask layer serves as an etch mask for plasma dicing of the processed wafer. For example, plasma dicing is performed from the back or bottom surface of the wafer.

In one embodiment, the die below the passivation stack includes scalloped sidewalls 218. For example, in the case of a rectangular-shaped die, the four sidewalls below the passivation stack have scalloped sidewalls. The scalloped sidewalls, in one embodiment, result from a plasma dicing process using deposition and etch cycles. For example, each deposition and etch cycle forms a scallop-shaped sub-portion. The scalloped sidewalls are plasma-etched sidewall surfaces.

Referring to FIG. 2d, another embodiment of a processed die 220 is shown. The processed die includes similar characteristics and elements as the dies described in FIGS. 2a-2c. Common elements may not be described or described in detail.

The processed die includes a substrate 211 processed with circuit components on the active or top surface 211_{T} thereof and a BEOL dielectric 230 thereover. A passivation stack 250 is disposed over the top of the BEOL dielectric. In one embodiment, the passivation stack includes multiple dielectric passivation layers. The passivation stack may include pad openings (not shown) to expose the bond pads for external connections to the internal circuit components of the die.

A bottom surface (BS) mask layer 270 is disposed on the bottom surface 211_{B} of a processed wafer of which the processed die is a part prior to singulation. In one embodiment, the BS mask layer is a patterned mask layer. Patterning the mask layer may be achieved by laser ablation or by mechanical dicing, such as sawing. For example, the mask layer sidewalls may be laser ablated or sawed surfaces. The mask layer sidewalls are vertical sidewalls. As shown, the patterned mask layer serves as an etch mask for plasma dicing of the processed wafer. For example, plasma dicing is performed from the back or bottom surface of the wafer.

The sidewalls of the processed die, as shown, include upper and lower sidewall portions 218_{U} and 218_{L}. As shown, the upper sidewall portion extends outwards away from the lower sidewall portion, creating a foot 213. The upper sidewall portion includes an upper substrate portion and the passivation stack. The upper substrate portion for example, is about 10-20% of the total thickness of the substrate while the lower sidewall portion is about 80-90% of the total thickness of the substrate. Other thicknesses for the upper and lower portions may also be useful. The upper portion, for example, should not exceed a thickness so as to enable force separation without damage.

In one embodiment, the upper portion includes a vertical or substantially vertical upper sidewall surface and the lower substrate sidewall portion includes a scalloped sidewall from plasma dicing. The profile of the foot is formed by partial plasma dicing of the wafer which is subsequently singulated by lateral force caused by laterally stretching the partially diced wafer away from the center thereof. As such, the lower sidewall portion includes a plasma diced surface and the upper sidewall portion includes a force separated surface 214.

As described, the dies include the patterned BS mask layer on the back surface of the substrate, providing backside protection for the dies. In addition, plasma dicing the wafer to singulate the wafer into dies improves yields and productivity over conventional blade or saw dicing.

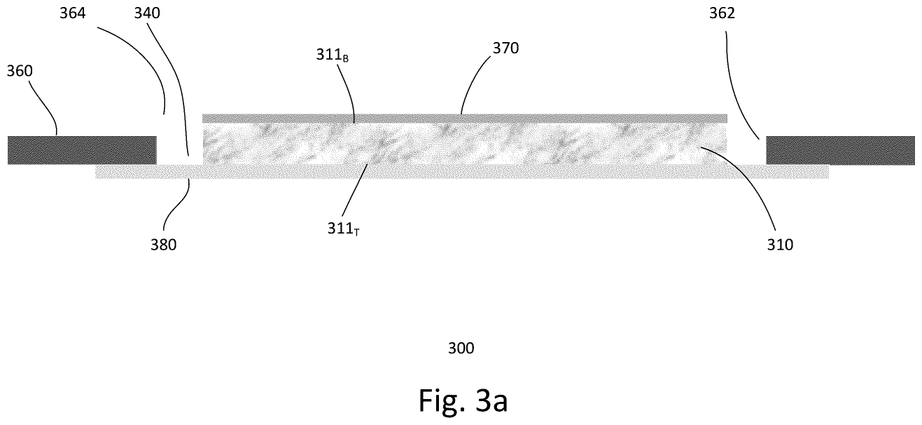

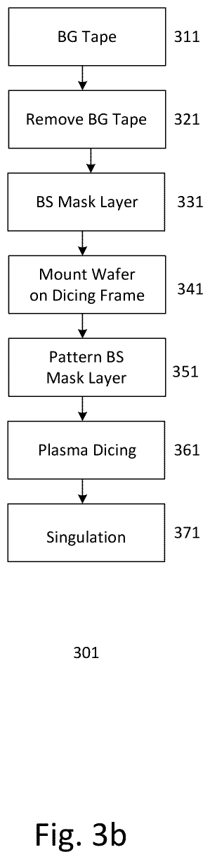

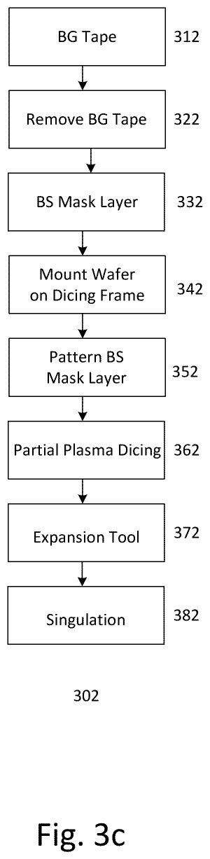

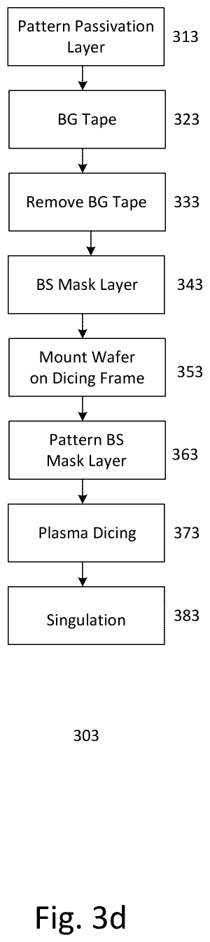

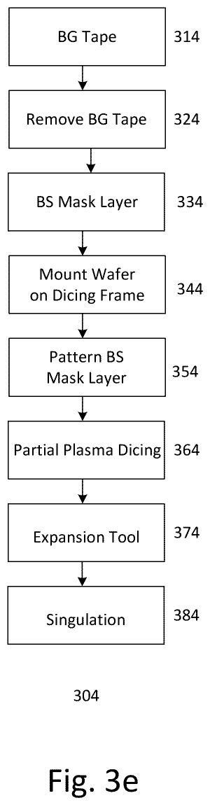

FIG. 3a shows an exemplary setup 300 for plasma dicing a wafer. As shown, a wafer ring assembly is provided. The wafer ring assembly includes a wafer ring frame 360 with a wafer ring frame opening 364 within the inner edge 362 of the frame. A dicing tape 380 is attached to a bottom surface of the wafer ring frame. In one embodiment, the dicing tape is an expandable dicing tape. An adhesive side of the dicing tape is facing upwards into the wafer ring frame opening. The opening is configured to accommodate a blank or a processed wafer 310. As shown, a gap 340 exists between the wafer and wafer ring frame.

The inactive or back surface 311B of the wafer includes a BS mask layer 370. For example, the BS mask layer is subsequently patterned to serve as a plasma dicing mask for the wafer. An opposing surface of the wafer is attached to the dicing tape. The opposing surface, for example, may be the top unprocessed surface 311T, in the case of an unprocessed wafer or a top surface of the passivation stack in the case of a processed wafer. The wafer is mounted on the dicing tape 380 attached to a wafer frame 360. The wafer frame and dicing tape may be referred to as a wafer frame assembly.

The BS mask layer is then patterned to form dicing channels in the x-direction and y-directions. Patterning the passivation layer may employ laser ablation or mechanical dicing, such as sawing. The wafer frame assembly with the wafer, after patterning the BS mask layer, is positioned into a plasma chamber for plasma dicing from the back surface of the wafer.

The exemplary setup is provided to merely described a general setup for plasma dicing. As described, the plasma dicing may be performed on a blank or processed wafer. Furthermore, plasma dicing may be performed to fully dice the wafer or partially dice the wafer.

FIGS. 3b-3e show various simplified process flows for plasma dicing a wafer. A process flow, as previously described, plasma dicing may be performed to dice, either an unprocessed or a processed wafer, from its back surface. Plasma dicing can be a full plasma dicing process or a partial plasma dicing process. In the case of a partially diced wafer, it is singulated using lateral force to break the remaining portion.

Referring to FIG. 3b, an embodiment of a process flow 301 for dicing an unprocessed wafer is shown. At 311, a backgrinding (BG) tape is attached to the top surface of the blank wafer. Backgrinding may be performed on the inactive wafer surface to thin the wafer to a desired thickness, such as, such as 50 to 300 microns (um). Thinning the wafer to other thicknesses or not thinning the wafer may also be useful. In some embodiments, for a thinned wafer, the thickness may be about 125 μm or less while for an unthinned wafer, it may be more than 125 um. Other thicknesses for thinned and unthinned wafers may also be useful. In some cases, no backgrinding is performed. In such cases, applying the BG tape to the wafer may be eliminated.

The BG tape is removed at 321. In the case where no backgrinding is performed, removal of the BG tape is also eliminated. At 331, a BS mask layer is attached to the back surface of the wafer. For example, the BS mask layer is laminated to the back surface of the wafer.

The wafer with the BS mask layer is mounted on a frame assembly at 341. For example, the top surface of the wafer is mounted onto the dicing tape of the wafer frame assembly. The BS mask layer, at 351, is patterned to expose the dicing channels on the back surface of the wafer. The wafer ring assembly with the wafer is then placed into a plasma dicing tool chamber at 361. The processed wafer is plasma diced, using the patterned BS mask layer as an etch mask. The plasma dicing, in one embodiment, fully patterns the wafer. For example, the portions of the wafer exposed by the patterned BS mask layer are fully removed. At 371, the singulated dies are removed from the dicing tape. The singulated dies may be similar to the die shown in FIG. 2a.

FIG. 3c shows another embodiment of a process flow 302 for dicing a blank wafer. The process flow may include similar processing, as described in FIG. 3b. Common processing may not be described or described in detail. At 312, a BG tape is attached to the blank wafer. Backgrinding may be performed on the inactive wafer surface to thin the processed wafer to a desired thickness. In some cases, backgrinding is not performed. In such cases, no BG tape is needed.

After backgrinding, the BG tape is removed at 322. A BS mask layer is attached to the back surface of the wafer at 332 and mounted onto a wafer frame assembly at 342. The BS mask layer, at 352, is patterned to expose the saw streets on the back surface of the wafer.

The wafer ring assembly is then placed into a plasma dicing tool chamber at 362. The wafer is plasma diced using the patterned BS mask layer as an etch mask. In one embodiment, the plasma dicing partially dices the wafer. For example, the plasma dicing forms partial dicing channels to a depth equal to about a depth of 80-90% of the thickness of the wafer.

After partial plasma dicing, the wafer frame assembly with the partially diced wafer is removed from the plasma etching tool and transferred to a singulation or expansion tool at 372. The singulation tool expands the dicing tape outwards from the center of the wafer frame to singulate the partially plasma diced wafer into individual dies at 382. The individual dies may be similar to the die described in FIG. 2b.

FIG. 3d shows yet another embodiment of a process flow 303 for dicing a processed wafer. The processed wafer may be similar to that described in FIGS. 1a-1b. The process flow may include similar processing, as those described in FIGS. 3b-3c. Common processing may not be described or described in detail.

At 313, the passivation stack over the BEOL of the processed wafer is mounted onto a wafer frame assembly. For example, the inactive surface of the wafer is mounted onto a wafer dicing tape attached to a wafer frame. The passivation layer is patterned to expose, for example, the kerf regions. For example, dicing channels are exposed in the x and y directions of the processed wafer.

A BG tape is attached to the processed wafer at 323. The BG tape is applied to the surface of the patterned passivation stack. Backgrinding may be performed on the inactive wafer surface to thin the processed wafer to a desired thickness. In some cases, backgrinding is not performed. In such cases, no BS tape is needed. After backgrinding, at 333, the BG tape is removed.

At 343, a BS mask layer is attached to the back surface of the wafer. The wafer with the BS mask layer is mounted on a wafer frame assembly at 353. For example, the top surface of the patterned passivation stack is mounted onto the dicing tape of the wafer frame assembly. The BS mask layer, at 363, is patterned to expose the dicing channels on the back surface of the wafer. Preferably, the dicing channels of the BS mask layer match the openings of the patterned passivation stack. By matching, it is understood that there may be processing variations. Matching, in this case, includes process variations which are within acceptable limits.

The wafer ring assembly with the wafer is then placed into a plasma dicing tool chamber at 373. The processed wafer is plasma diced, using the patterned BS mask layer as an etch mask. The plasma dicing, in one embodiment, fully patterns the wafer. For example, the portions of the wafer exposed by the patterned BS mask layer are fully removed to singulate the wafer into individual dies. At 383, the singulated dies are removed from the dicing tape. The singulated dies may be similar to the die shown in FIG. 2c.

Another embodiment of a process flow 304 for dicing a processed wafer is shown in FIG. 3e. The processed wafer may be similar to that described in FIGS. 1a-1b. The process flow may include similar processing, as those described in FIGS. 3b-3d. Common processing may not be described or described in detail.

At 314, a BG tape is attached to the top surface of the processed wafer. The BG tape is applied to the top of the passivation stack. Backgrinding may be performed on the inactive wafer surface to thin the wafer to a desired thickness. In some cases, no backgrinding is performed. In such cases, applying the BG tape to the wafer may be eliminated.

The BG tape is removed at 324. In the case where no backgrinding is performed, removal of the BG tape is also eliminated. At 334, a BS mask layer is attached to the back surface of the wafer. The wafer with the BS mask layer is mounted on a frame assembly at 344. For example, the top surface of the patterned passivation stack is mounted onto the dicing tape of the wafer frame assembly. The BS mask layer, at 354, is patterned to expose the dicing channels on the back surface of the wafer.

The wafer ring assembly with the wafer is then placed into a plasma dicing tool chamber at 364. The wafer is plasma diced, using the patterned BS mask layer as an etch mask. In one embodiment, the plasma dicing partially dices the wafer. For example, the plasma dicing forms partial dicing channels to a depth equal to about a depth of 80-90% of the thickness of the wafer.

After partial plasma dicing, the wafer frame assembly with the partially diced wafer is removed from the plasma etching tool and transferred to a singulation or expansion tool at 374. The singulation tool expands the dicing tape outwards from the center of the wafer frame to singulate the partially plasma diced wafer into individual dies at 384. The individual dies may be similar to the die described in FIG. 2d.

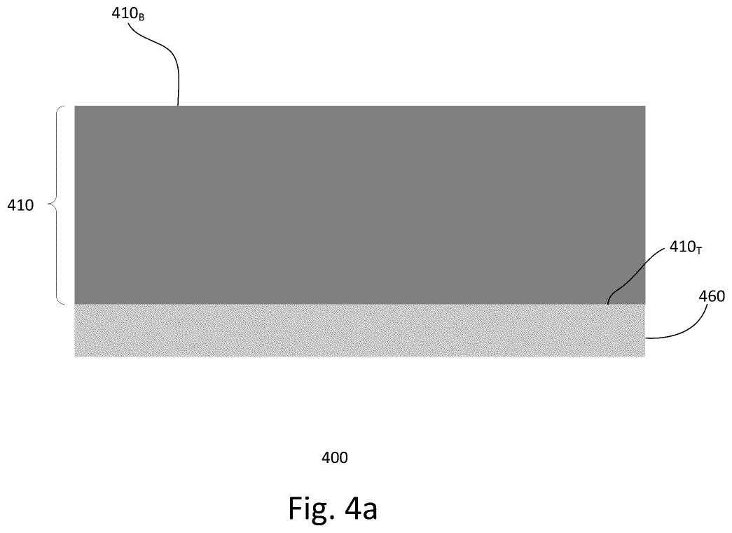

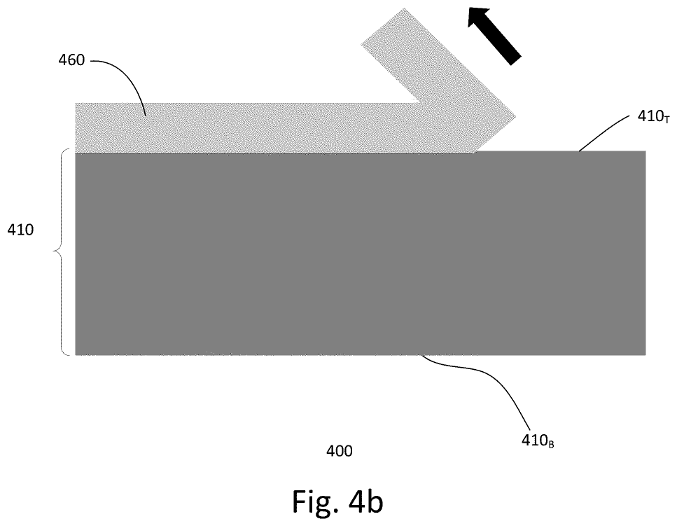

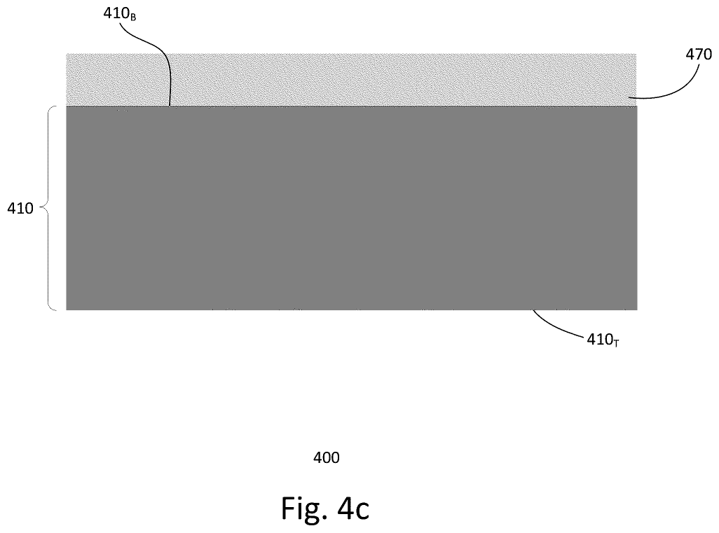

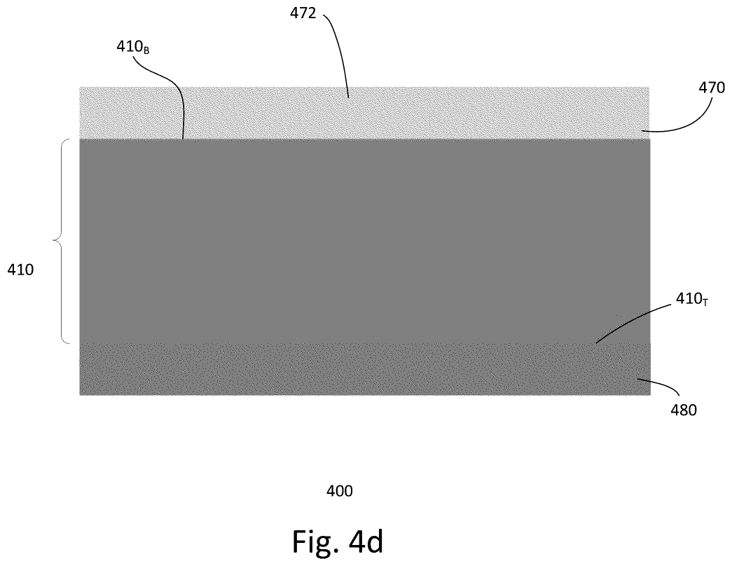

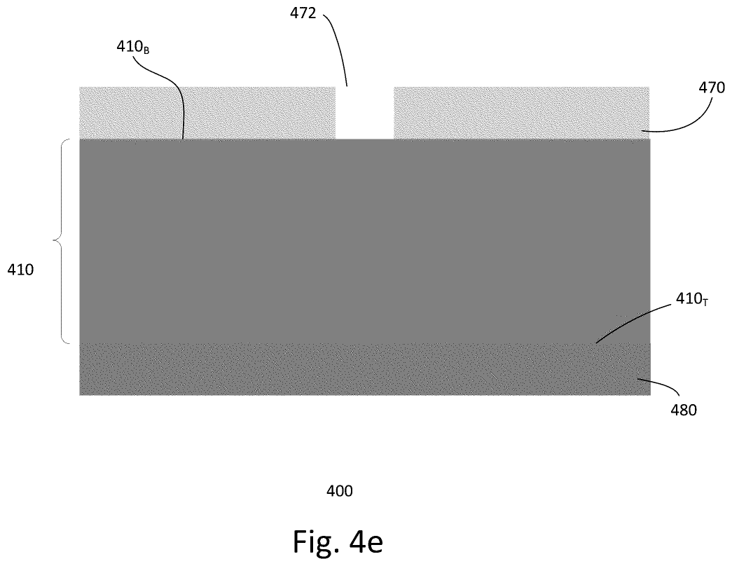

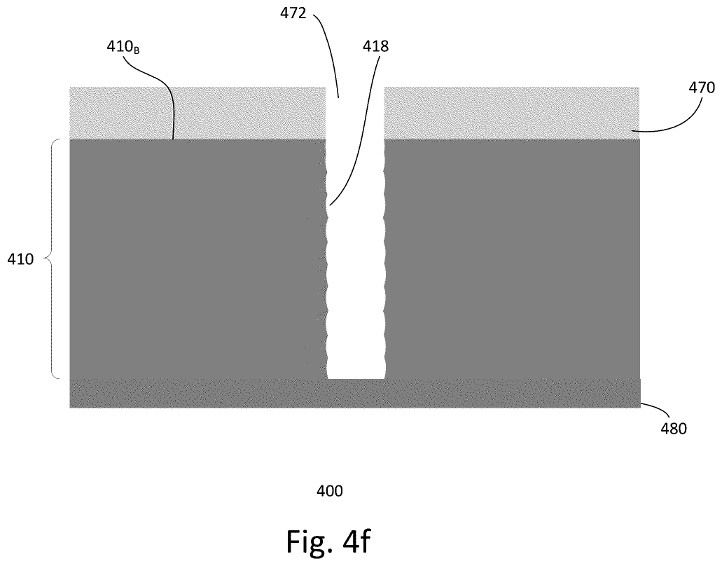

FIGS. 4a-4f show simplified cross-sectional views of an embodiment of a process 400 for plasma dicing a blank wafer to singulate it into individual blank dies. Illustratively, a portion of the wafer is shown. The wafer and portion of the wafer may be similar to that shown in FIGS. 1a-1b (except that it is a blank wafer) and the dies are similar to the die described in FIG. 2a. The process is similar to that described in FIG. 3b. Common elements may not be described or described in detail.

Referring to FIG. 4a, the portion of the blank wafer 410 includes two adjacent dies separated by a saw street. The cross-sectional view may be in the x-direction or the y-direction. Since the wafer is a blank wafer, there is no kerf region necessary for test structures. The blank wafer 410 includes a wafer top surface 410_{T} and a wafer bottom surface 410_{B}. A BG tape 460 is attached to the wafer top surface. This leaves the inactive surface of the wafer exposed. In some embodiments, the inactive surface of the wafer may be ground to thin the wafer to the desired thickness. Alternatively, no grinding of the wafer is performed. In such cases, no BG tape is necessary.

In FIG. 4b, after backgrinding, the BG tape 460 is removed from the top wafer surface 410_{T}.

As shown in FIG. 4c, a BS mask layer 470 is laminated on the bottom or back surface 410E of the wafer. Other techniques for attaching the BS mask layer to the back surface of the wafer may also be useful. The back surface of the wafer may be a ground or unground surface. In one embodiment, the BS mask layer is an infrared (IR) mask layer. Other types of BS mask layers may also be useful. In some embodiments, the mask layer may be a non-IR mask layer.

In FIG. 4d, the wafer with the BS mask layer 470 is mounted onto a wafer frame assembly. In one embodiment, a top surface 410_{T} of the wafer is attached to a dicing tape 480 of the wafer frame assembly. The wafer is aligned onto the wafer dicing frame and attached to the dicing tape.

After mounting the wafer onto the wafer frame assembly, the BS mask layer 470 is patterned, as shown in FIG. 4e. For example, the BS mask layer is patterned to form mask openings 472 defining plasma dicing channels in both the x and y-directions. Patterning of the BS mask layer may be achieved using, for example, laser ablation or mechanical dicing, such as sawing. Other techniques for patterning the BS mask layer may also be useful.

Referring to FIG. 4f, the wafer frame assembly with the wafer having the patterned BS mask layer 470 is inserted into a plasma dicing chamber. The wafer is plasma diced using the patterned BS mask layer as a plasma dicing mask. The plasma completely etches portions of the wafer exposed by the patterned BS mask. For example, the dicing channels of the wafer are completely diced to expose the wafer dicing tape. The chemistry employed selectively removes the wafer material without removing the wafer dicing tape and the BS mask. The plasma etch may be a timed control etch which completely etches the thickness of the wafer and stops when the wafer dicing tape is exposed.

In one embodiment, the wafer sidewalls in the dicing channels, as shown, include scalloped sidewalls 418. The scalloped sidewalls, in one embodiment, result from a plasma dicing process using deposition and etch cycles. For example, each deposition and etch cycle forms a scalloped sub-portion. The scalloped sidewalls, as such, are plasma-etched sidewall surfaces.

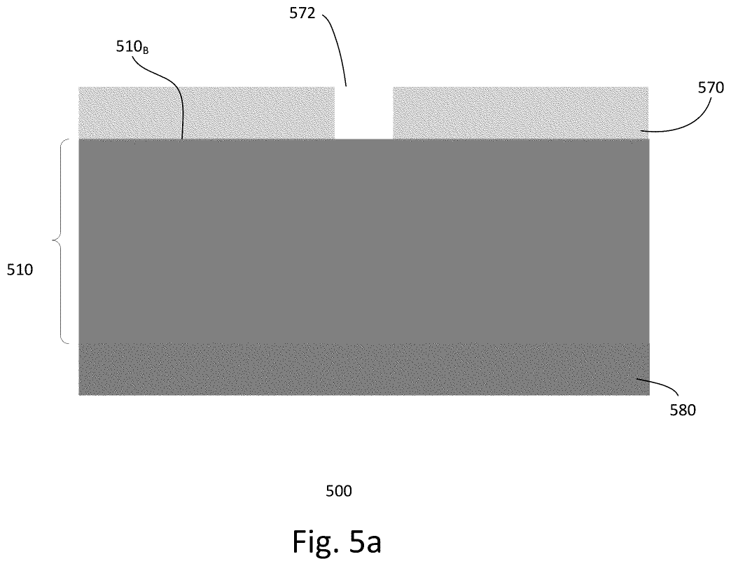

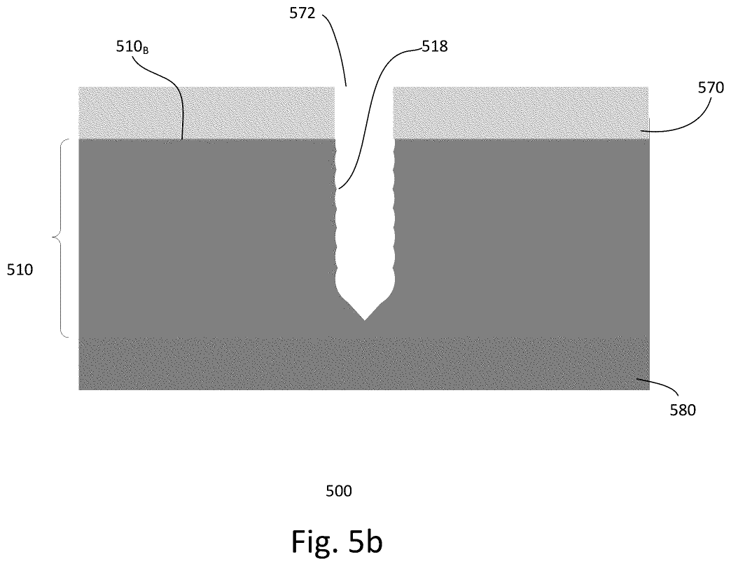

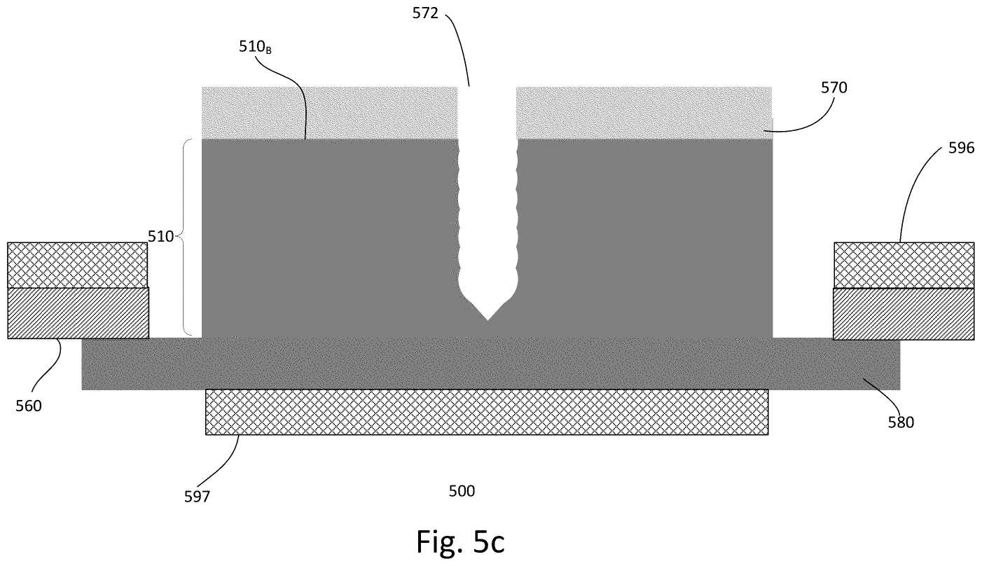

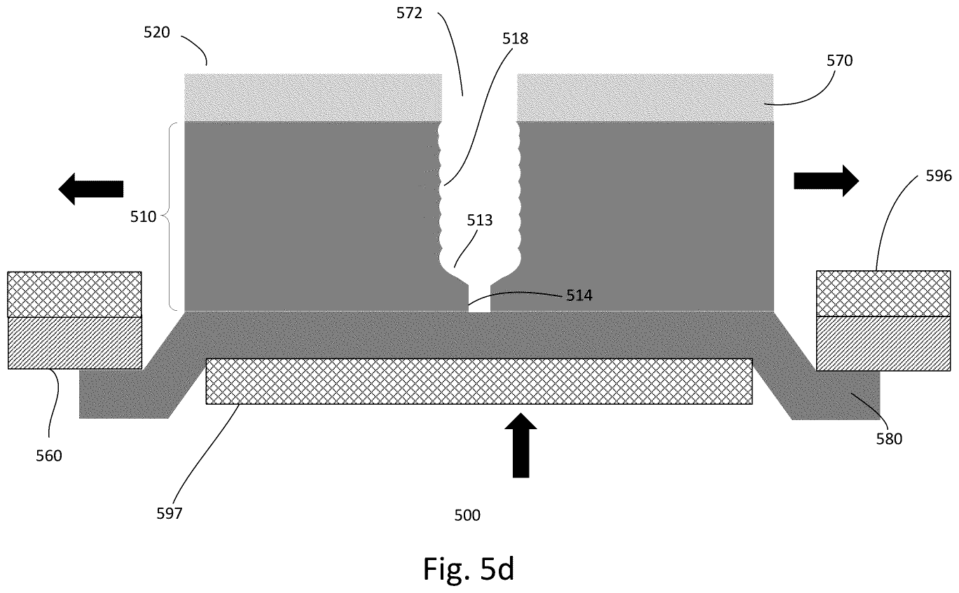

FIGS. 5a-5d show simplified cross-sectional views of another embodiment of a process 500 for plasma dicing a blank wafer to singulate it into individual blank dies. Illustratively, a portion of the wafer is shown. The process is similar to that described in FIG. 4a-4f Common elements may not be described or described in detail.

Referring to FIG. 5a, the portion of the blank wafer 510 includes two adjacent blank dies with a saw street therebetween. The wafer 510, as shown, is at the stage of processing as described in FIG. 4e. For example, the blank wafer is attached to a dicing tape 580 of a wafer frame assembly and includes a patterned BS mask layer 570 on the wafer back surface 510B. The patterned BS mask layer includes mask openings 572 which expose dicing channels of the wafer in the x and y-directions.

Referring to FIG. 5b, the wafer frame assembly with the wafer 510 having the patterned BS mask layer 570 is inserted into a plasma dicing chamber. The wafer is plasma diced using the patterned BS mask layer as a plasma dicing mask. In one embodiment, the plasma process partially etches portions of the wafer exposed by the patterned BS mask. For example, the dicing channels of the wafer are diced to a depth of about 80-90% of the total thickness of the blank wafer. This leaves a remaining portion equal to about 10-20% of the total thickness of the blank wafer. The chemistry employed selectively removes the wafer material without removing the BS mask. The plasma etch may be a timed control etch which stops etching when the desired depth of the wafer is reached. In one embodiment, the wafer sidewalls in the dicing channels, as shown, include scalloped sidewalls 518.

In FIG. 5c, after partial plasma dicing, the dicing tape 580 is attached to a film expansion tool 596. A clamp 596 of the film expansion tool holds the wafer frame 560 in position. The expansion tool also includes a tape expansion fixture 597. As shown, the fixture is disposed below the dicing tape.

Referring to FIG. 5d, the dicing tape is expanded laterally from the center of the wafer. The tape expansion fixture 597 is employed to press on the wafer ring assembly to ensure the tape is evenly expanded, breaking the remaining portion of the wafer. For example, the fixture is pressed against the dicing tape as it is elevated upwards to expand the dicing tape to singulate the wafer into individual dies. In one embodiment, a side surface of a singulated die includes a foot 513 with a vertical sidewall 514 which is a force separated surface. This completes the singulation process.

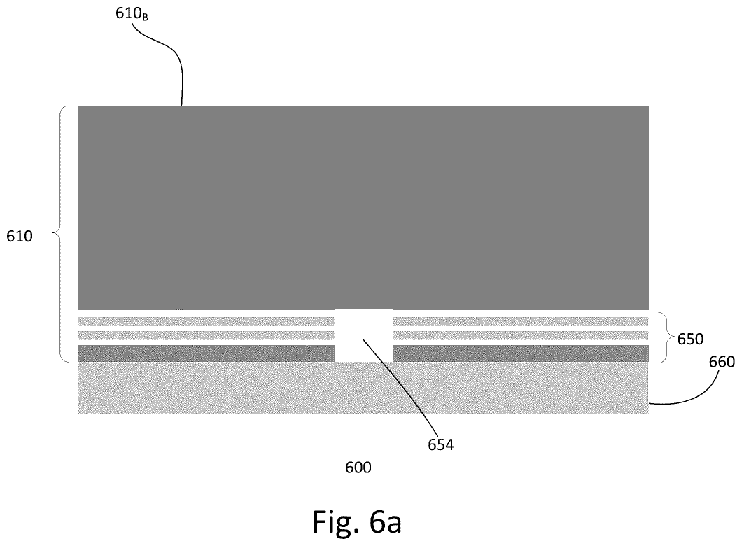

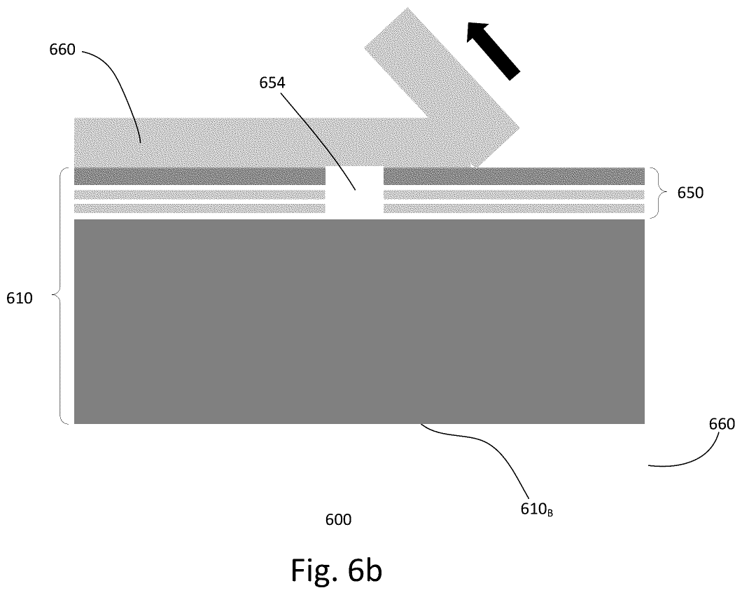

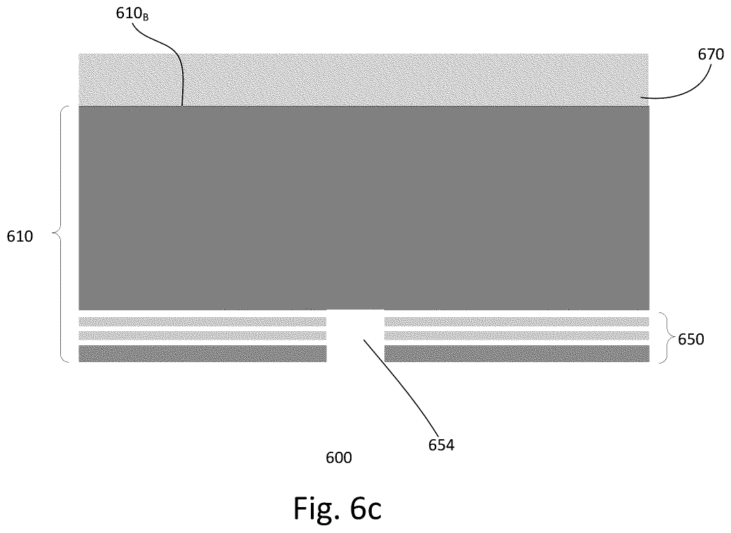

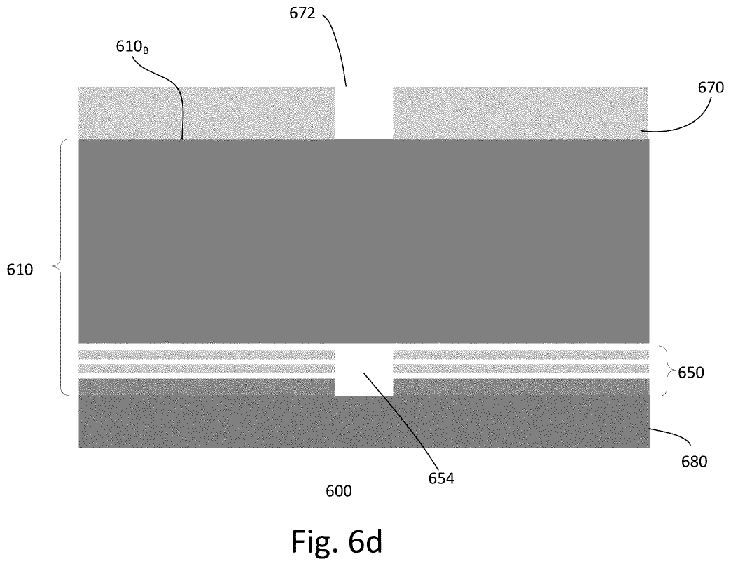

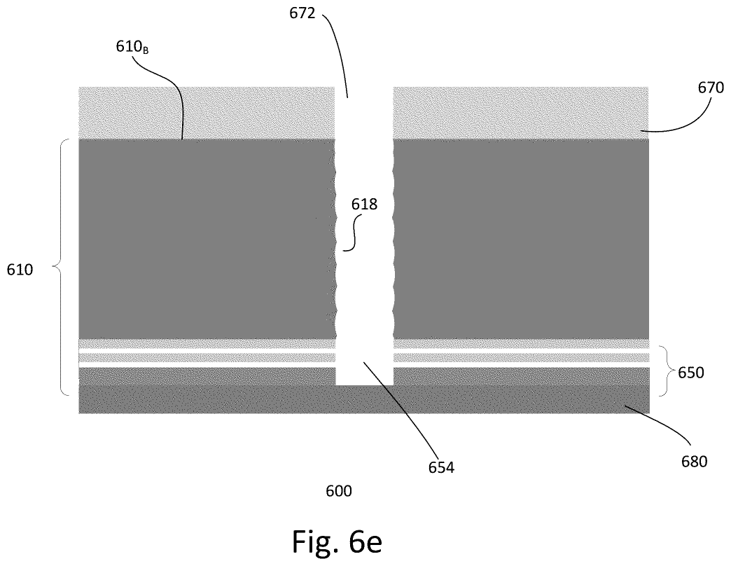

FIGS. 6a-6e show simplified cross-sectional views of an embodiment of a process 600 for plasma dicing a processed wafer to singulate it into individual dies. Illustratively, a portion of the wafer is shown. The process is similar to that described in FIGS. 2d, 4a-4f and 5a-5d. The dies may be similar to the die described in FIG. 2c. Common elements may not be described or described in detail.

Referring to FIG. 6a, the portion of the processed wafer 610 shown includes two adjacent dies with a saw street therebetween and a kerf region therein. Gap regions separate the edges of the saw street and kerf region. The processed wafer 610 includes a wafer with circuit components formed over the wafer active surface, a BEOL dielectric with interconnects over the wafer circuit components on the wafer active surface and a passivation stack 650 on the BEOL dielectric.

In one embodiment, the passivation stack is patterned to expose the kerf regions in the x and y-directions. For example, the passivation stack is patterned to expose the dicing channels of the wafer. Patterning the passivation stack, for example, may be achieved using laser patterning. Other techniques for patterning the passivation stack may also be useful. As shown, the patterning of the passivation stack forms vertical passivation sidewalls.

A BS tape 660 is attached to the processed wafer. For example, the BS tape is attached to the surface of the patterned passivation stack with openings 654. The openings, for example, correspond to the dicing channel on the active surface of the wafer. This leaves the inactive surface of the wafer 610B exposed. In some embodiments, the inactive surface of the wafer may be ground to thin the processed wafer to the desired thickness. Alternatively, no grinding of the wafer is performed. If no backgrinding is performed, the BS tape is not necessary.

In FIG. 6b, after backgrinding, the BS tape 660 is removed. In the case no backgrinding is performed, removal of the BS tape is also not necessary since no BS tape is needed.

Referring to FIG. 6c, a BS mask layer 670 is laminated on the bottom or back surface 610B of the processed wafer. Other techniques for attaching the BS mask layer to the back surface of the wafer may also be useful. The back surface of the wafer may be a ground or unground surface. In one embodiment, the BS mask layer is an infrared (IR) mask layer. Other types of BS mask layers may also be useful. In some embodiments, the mask layer may be a non-IR mask layer.

In FIG. 6d, the wafer with the patterned BS mask is mounted onto a wafer frame assembly. In one embodiment, a top surface of the patterned passivation stack is attached to a dicing tape 680 of a wafer frame assembly. For example, the wafer is aligned onto the wafer dicing frame and attached to the dicing tape.

After mounting the wafer onto the wafer frame assembly, the BS mask layer 670 is patterned, as shown in FIG. 6e. For example, the BS mask layer is patterned to form mask openings 672 defining plasma dicing channels in both the x and y-directions. Patterning of the BS mask layer may be achieved using, for example, laser ablation or mechanical dicing, such as sawing. Other techniques for patterning the BS mask layer may also be useful. In one embodiment, the BS mask openings correspond to the passivation stack openings. As shown, the BS mask openings include vertical sidewalls.

Referring to FIG. 6e, the wafer frame assembly with the wafer having the patterned BS mask layer and patterned passivation stack is inserted into a plasma dicing chamber. The wafer is plasma diced using the patterned BS mask layer as a plasma dicing mask. The plasma completely etches portions of the wafer exposed by the patterned BS mask. For example, the wafer is completely diced to expose the wafer dicing tape. The chemistry employed selectively removes the wafer material without removing the wafer dicing tape, the BS mask and the passivation stack. The plasma etch may be a timed control etch which completely etches the thickness of the wafer and stops when the wafer is completely diced to expose the dicing tape.

In one embodiment, the wafer sidewalls in the dicing channels, as shown, include scalloped sidewalls 618. The scalloped sidewalls, in one embodiment, result from a plasma dicing process using deposition and etch cycles. For example, each deposition and etch cycle forms a scalloped sub-portion. The scalloped sidewalls, as such, are plasma-etched sidewall surfaces. As for the passivation stack and BS mask sidewalls, they remain vertical sidewalls. The plasma dicing process singulates the wafer into individual dies. The dies are then subsequently removed from the dicing tape, completing the singulation process.

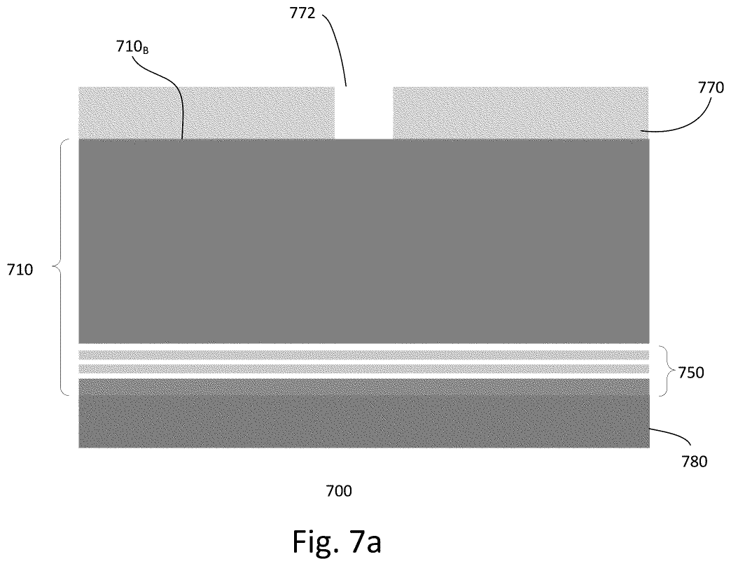

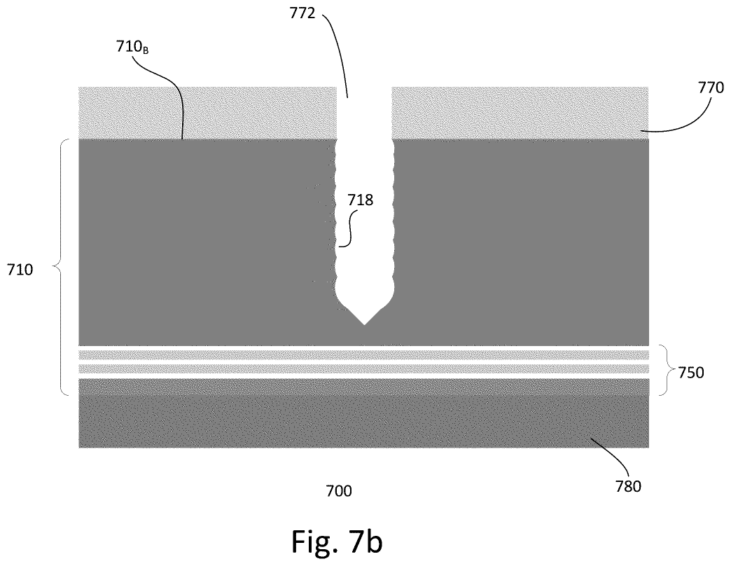

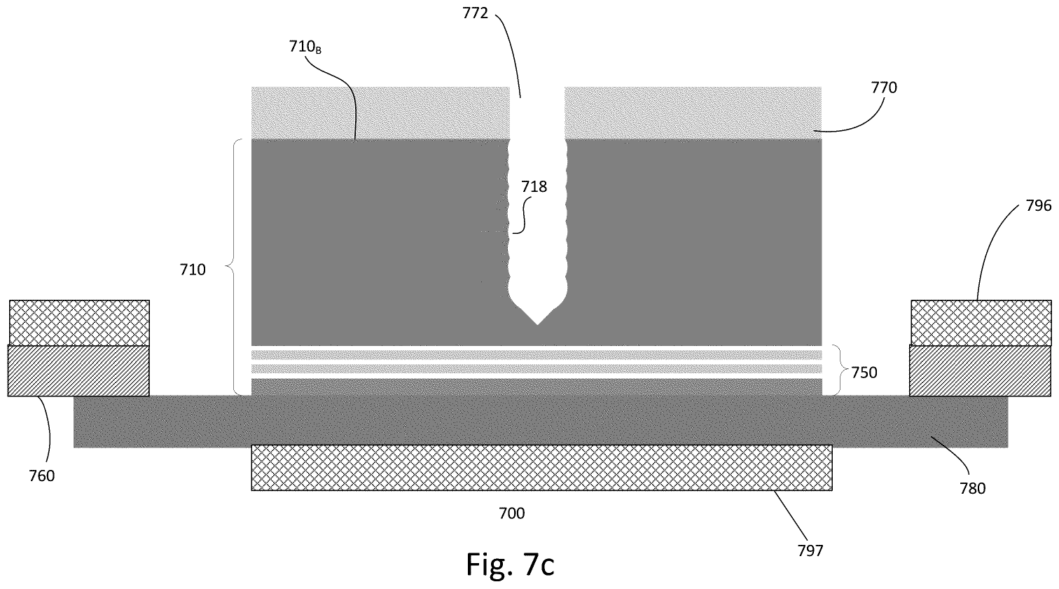

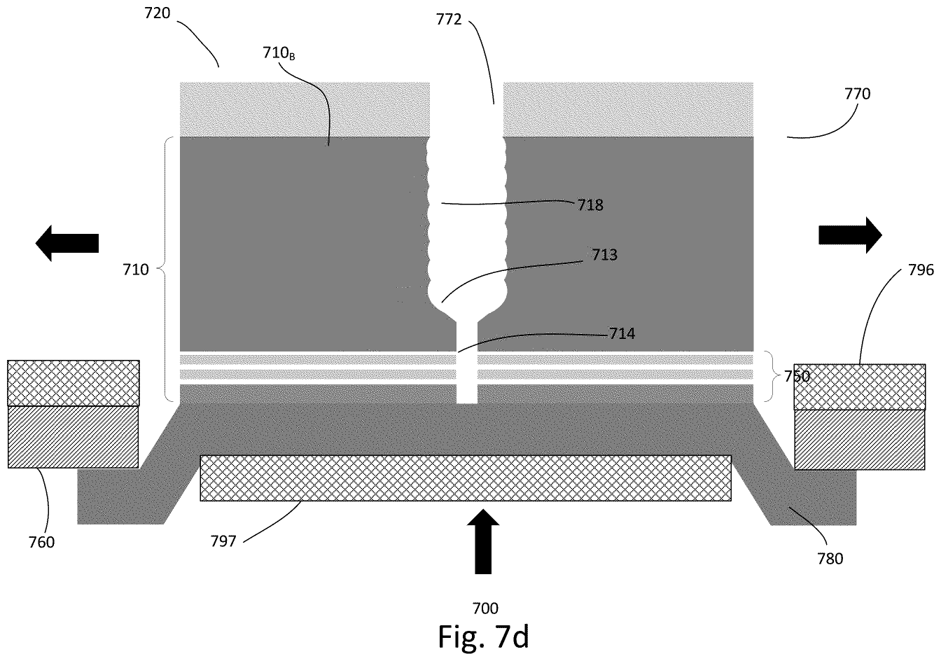

FIGS. 7a-7d show simplified cross-sectional views of another embodiment of a process 700 for plasma dicing a processed wafer to singulate it into individual dies. Illustratively, a portion of the wafer is shown. The wafer and portion of the wafer are similar to that shown in FIGS. 1a-1b and the dies are similar to the die described in FIG. 2d. The process is similar to that described in FIG. 3d, 4a-4f, 5a-5d and 6a-6e. Common elements may not be described or described in detail.

Referring to FIG. 7a, the portion of the processed wafer 710 includes two adjacent dies with a saw street therebetween. The wafer 710, as shown, is at the stage of processing as described in FIG. 6d. For example, the processed wafer includes a passivation stack which is attached to a dicing tape 780 of a wafer frame assembly and includes a patterned BS mask layer 770 on the wafer back surface 710B. The patterned BS mask layer includes mask openings 772 which expose dicing channels of the wafer in the x and y-directions.

Referring to FIG. 7b, the wafer frame assembly with the wafer having the patterned BS mask layer is inserted into a plasma dicing chamber. The wafer is plasma diced using the patterned BS mask layer as a plasma dicing mask. In one embodiment, the plasma process partially etches portions of the wafer exposed by the patterned BS mask. For example, the dicing channels of the wafer are diced to a depth of about 80-90% of the total thickness of the blank wafer. This leaves a remaining portion equal to about 10-20% of the total thickness of the blank wafer. The chemistry employed selectively removes the wafer material without removing the BS mask. The plasma etch may be a timed control etch which stops etching when the desired depth of the wafer is reached. In one embodiment, the wafer sidewalls in the dicing channels, as shown, include scalloped sidewalls 718.

In FIG. 7c, after partial plasma dicing, the dicing tape is attached to a film expansion tool 796. A clamp 796 of the film expansion tool holds the wafer frame 760 in position. The expansion tool also includes a tape expansion fixture 797. As shown, the fixture is disposed below the dicing tape 780.

Referring to FIG. 7d, the dicing tape 780 is expanded laterally from the center of the wafer. The tape expansion fixture 797 is employed to press on the wafer ring assembly to ensure the tape is evenly expanded, breaking the remaining portion of the wafer. For example, the fixture is pressed against the dicing tape as it is elevated upwards to expand the dicing tape to singulate the wafer into individual dies. In one embodiment, a side surface of a singulated die includes a foot 713 with a vertical sidewall 714 which is a force separated surface. This completes the singulation process.

As described, some embodiments include partially dicing the wafer and using force by expanding the dicing tape to complete the singulation process. Partial dicing and using force to singulate the wafer is particularly useful in the case where the wafer includes materials which are selective to the etch chemistry, such as the passivation stack. This eliminates cross-contamination of the etch chamber due to the different chemistries, requiring cleaning. Avoiding the need to clean the chamber due to different processes increases cycle time.

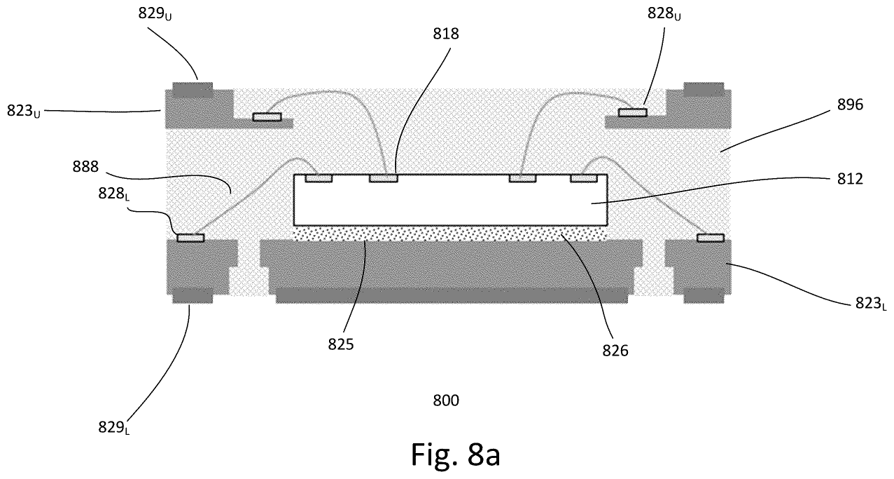

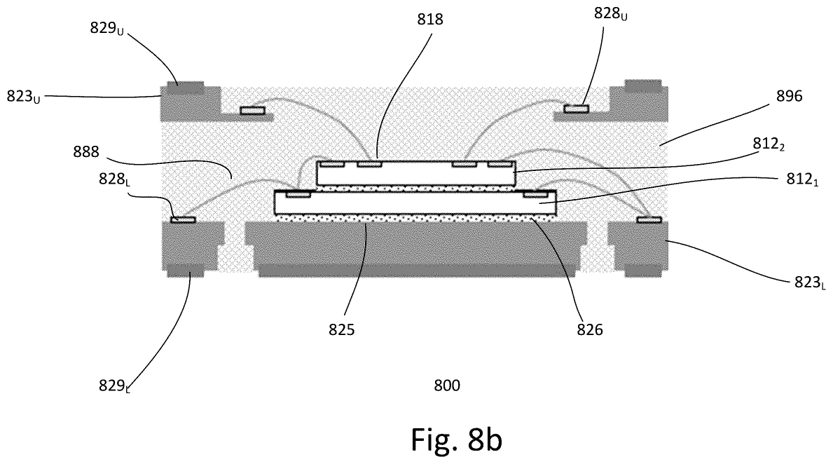

FIG. 8a shows a simplified cross-sectional view of an embodiment of a package 800. The package, for example, is a semiconductor package. The package, as shown, includes lower and upper leadframes 823_{L} and 823_{U}. The lower leadframe forms the bottom portion of the package while the upper leadframe forms a top portion of the package. The leadframes, for example, may be copper or copper alloy leadframes. Other types of conductive leadframes may also be useful. The lower leadframe includes a die attach region 825 and lower frame pads 828_{L} on a top surface thereof. For example, the lower frame pads may be disposed on lower frame fingers. Lower package contacts 829_{L} are disposed on a bottom surface of the lower leadframe. The lower package contacts are electrically coupled to the lower frame pads.

The die attach region is configured to accommodate a die 812 of the package. The die includes active and inactive surfaces. The active surface, in one embodiment, includes die pads 818 which have external access to the die. The inactive surface of the die, for example, is attached to the leadframe by an adhesive 826. The adhesive may be a curable adhesive dispensed on the die attach region or an adhesive tape. Other types of adhesives may also be useful.

As for the upper leadframe, it includes upper leadframe fingers on upper frame pads 828_{U}. As shown, the upper frame pads are disposed on a top surface of the upper leadframe fingers. In one embodiment, the fingers may have a stepped profile. Other configurations of the leadframe fingers may also be useful. A top surface of the lead frame includes upper package contacts 829_{U}. The upper package contacts are electrically connected to the upper frame pads.

Wire bonds 888 are provided to electrically couple the dies to the frame pads. For example, wire bonds coupled the die pads to the upper and lower frame pads. An encapsulant 896 encapsulates the die and the leadframes, die and wire bonds. The encapsulant, for example, may be a mold compound. Other types of encapsulants may also be useful.

In one embodiment, the encapsulant includes first and second encapsulants. The first encapsulant, for example, encapsulates the lower leadframe and leaves the lower package pads exposed. The first encapsulant also forms a cavity to expose the die attach region on the top surface of the lower leadframe. The second encapsulate encapsulates the die, wire bonds and upper leadframe, leaving the upper package pads exposed. Other configurations of encapsulants may also be useful.

As described, the package includes upper and lower package contacts on the top and bottom package surfaces.

FIG. 8b shows another embodiment of a package 800. The package is similar to the package of FIG. 8a. Common elements may not be described or described in detail. As shown, the package includes a stacked die package with package contacts on the top and bottom surface of the package. The stacked die package, for example, includes a die stack with first and second dies 812₁₋₂. Other configurations of dies for a multi-die package may also be useful. For example, the multi-die package may include die stacks have more than 2 dies, non-stacked dies or a combination of stacked and non-stacked dies.

The present disclosure may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. A device comprising:
a die comprising
first and second major die surfaces, and
die sidewalls, wherein at least a portion of the die sidewalls extending from the second major die surface towards the first major die surface comprises scalloped-shaped sidewalls; and
a mask layer disposed on the second major die surface.

2. The device of claim 1 wherein the mask comprises a patterned mask to serve as a plasma dicing mask, wherein mask sidewalls comprise laser-ablated sidewalls.

3. The device of claim 1 wherein the mask comprises a patterned mask to serve as a plasma dicing mask, wherein mask sidewalls comprise mechanical-diced sidewalls.

4. The device of claim 1 wherein the die comprises a blank die.

5. The device of claim 4 wherein the scalloped-shaped sidewalls extend from the first die surface to the second die surface.

6. The device of claim 4 wherein the die sidewalls comprise a foot portion extending outwards from the scalloped-shaped sidewalls.

7. The device of claim 6 wherein foot sidewalls of the foot portion comprise forced separated sidewalls.

8. The device of claim 1 wherein the die comprises an active die, wherein the active die comprises:
a die substrate having first and second die substrate surfaces, wherein the first die substrate surface serves as an active die substrate surface with circuit components and the second die substrate surface serves as an inactive die substrate surface, the inactive die substrate surface is the die second surface;
a BEOL dielectric disposed on the active die substrate surface with the circuit components, the BEOL dielectric includes interconnects interconnecting the circuit components;
a passivation layer disposed on a top surface of the BEOL dielectric; and
wherein the scalloped-shaped die sidewalls comprise die substrate sidewalls and at least a portion of BEOL sidewalls of the BEOL dielectric.

9. The device of claim 8 wherein the scalloped-shaped sidewalls extend from the inactive die substrate surface to the top BEOL surface.

10. The device of claim 8 wherein:
the die sidewalls comprise a foot portion extending outwards from the scalloped-shaped sidewalls; and
the foot portion comprises passivation layer sidewalls and an upper portion of the BEOL dielectric.

11. The device of claim 10 wherein foot sidewalls of the foot portion of the BEOL dielectric comprise forced separated sidewalls.

12. The device of claim 11 wherein passivation sidewalls of the passivation layer in the foot portion comprises patterned sidewalls.

13. A semiconductor package comprising:
a lower leadframe, the lower leadframe includes
lower leadframe top surface,
lower leadframe bottom surface,
lower leadframe pads on the lower leadframe top surface,
a die attach region on the lower leadframe top surface, and
lower leadframe package contacts on the lower leadframe bottom surface, the lower leadframe package contacts are coupled to the lower leadframe pads;
an upper leadframe, the upper leadframe includes
upper leadframe top surface,
upper leadframe bottom surface,
upper leadframe pads on the upper leadframe top surface, and
upper leadframe package contacts on the upper leadframe top surface, the upper leadframe package contacts are coupled to the upper leadframe pads;
a die comprising active and inactive die surfaces, wherein the inactive die surface is attached to the die attach region of the lower leadframe package and the active die surface includes die pads;
wire bonds connecting the die pads to the upper and lower leadframe pads; and
an encapsulant encapsulating the upper and lower leadframes, the die and the wirebonds, wherein the upper and lower package contacts are exposed by the encapsulant.

14. A method of forming devices comprising:
providing a wafer, wherein the wafer comprises
a first major surface,
a second major surface; and
forming a mask layer on the second wafer surface;
patterning the mask layer to form a patterned mask layer with openings corresponding to dicing channels in x and y directions;
plasma dicing the wafer using the patterned mask layer; and
singulating the wafer into individual die.

15. The method of claim 14 wherein the wafer comprises a blank wafer, wherein singulating the wafer into individual dies singulates the wafer into individual blank dies.

16. The method of claim 15 plasma dicing the wafer comprises
plasma dicing the wafer from the first and second major surfaces; and
the plasma dicing forms scalloped-shaped die sidewalls for dies of the wafer.

17. The method of claim 15 plasma dicing the wafer comprises
plasma dicing the wafer partially, leaving a remainder portion;
the plasma dicing forms scalloped-shaped die sidewalls; and
force breaking the remainder portion to singulate the wafer into individual dies, wherein force breaking forms a foot portion in the remainder portion which extends out for the scalloped-shaped die sidewalls.

18. The method of claim 14 wherein the wafer comprises a processed wafer with a plurality of active dies, wherein singulating the wafer into individual dies singulates the wafer into individual active dies.

19. The method of claim 18 wherein plasma dicing the wafer comprises
plasma dicing the wafer from the first and second major surfaces; and
the plasma dicing forms scalloped-shaped die sidewalls for the active dies.
